(19) United States
(12) Patent Application Publication
(10) Pub. No.: US 2009/0246706 A1
(43) Pub. Date: Oct. 1, 2009

(54) PATTERNING RESOLUTION ENHANCEMENT COMBINING INTERFERENCE LITHOGRAPHY AND SELF-ALIGNED DOUBLE PATTERNING TECHNIQUES

(75) Inventors: RUDOLF HENDEL, Los Gatos, CA (US); Zhilong Rao, Stanford, CA (US); Kuo-Shih Liu, Fremont, CA (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/060,612

(22) Filed: Apr. 1, 2008

(51) Int. Cl. G03F 7/20; G03F 7/26

(52) U.S. Cl. 430/314; 430/323

(57) ABSTRACT

A method for providing regular line patterns using interference lithography and sidewall patterning techniques is provided according to one embodiment. The method comprising may include producing regularly spaced parallel lines on a template using interference lithography techniques and then depositing sidewalls on the longitudinal sides of the regularly spaced parallel lines using sidewall patterning techniques. Various deposition and etching steps may also be included. The embodiments of the invention may provide regular line patterns with a line density half the interference lithography line density. Various lithography techniques may also be used to crop rounded connecting resulting from the sidewall patterning and/or to alter portions of the line pattern.

### BACKGROUND

This disclosure relates in general to lithography techniques and, but not by way of limitation, to interference lithography in combination with self-aligned double patterning techniques among other things.

Optical resolution for lithography is determined by Rayleigh's equation. For the state of the art ArF lithography systems, the optical resolution is limited to 63 nm half pitch (HP) with a numerical aperture (NA) of 0.93 and K₁ factor at 0.3. There is a general push to provide lithography techniques that provide smaller and smaller resolutions.

Immersion lithography has also been proposed. Immersion lithography techniques replace the usual air gap between the final lens and a wafer surface with a liquid medium that has a refractive index greater than one. In such systems, the resolution may be reduced by a factor equal to the refractive index of the liquid. Current immersion lithography tools use highly purified water for the immersion liquid, and can achieve feature sizes below the Rayleigh limit. Immersion lithography, however, suffers from various manufacturing defects, such as, water marks, drying stains, water leaching, wafer edge peeling, and air bubbles that restrict full scale manufacturing efforts. Current development focuses on various manufacturing techniques that avoid these negative effects. The optical resolution for water-immersion lithography with an NA of 1.35 and K₁ factor of 0.3 is limited to 42 nm HP, per Rayleigh's equation. Further research is being conducted to seek lens materials, immersion fluids and photoresists with higher index of refraction to further reduce the resolution limit. However, few breakthroughs have been reported making it an unlikely candidate as the technology of choice for the next generation lithography.

Others have suggested using extreme ultraviolet (EUV) lithography as another solution to providing optical resolution below Rayleigh's limit for 193 nm optical lithography. Systems currently under development use 13.5 nm wavelength light sources. Various problems must be resolved before EUV lithography can be implemented; for example, low source power, contamination issues, and manufacturing and handling masks. These challenges have limited EUV lithography as a viable solution to extendible next-generation lithography technique.

Accordingly, there remains a general need in the art for a optical lithography system that can provide smaller and smaller optical resolution.

### BRIEF SUMMARY

A method for providing regular line patterns using interference lithography and sidewall patterning techniques is provided according to one embodiment. The method comprising may include producing regularly spaced parallel lines on a template using interference lithography techniques and then depositing sidewalls on the longitudinal sides of the regularly spaced parallel lines using sidewall patterning techniques. Various deposition and etching steps may also be included. The embodiments of the invention may provide regular line patterns with a pitch which is half that of the interference lithography line patterns. Various lithography techniques may also be used to crop rounded connecting resulting from the sidewall patterning and/or to alter portions of the line pattern.

A method for providing an array of regularly spaced printed lines in a semiconductor device is provided according to another embodiment. The method may include any of the following steps in any order: 1) providing a semiconductor device, wherein the semiconductor device includes a plurality of layers including a substrate, hardmask and photoresist, 2) exposing a line pattern in the photoresist using interference lithography, wherein the line pattern has a first line width and a first line spacing, 3) developing the line pattern in the photoresist, wherein after the developing a photoresist line pattern is formed on the hardmask, 4) trimming the photoresist line pattern; wherein the resulting trimmed line pattern has a second line width and a second line spacing, the second line spacing is equal to approximately three times the second line width, and the second line spacing is wider than the first line spacing, 5) etching the hardmask, wherein after the etching a hardmask line pattern is formed in the hardmask, 6) removing the photoresist from the template, 7) depositing a spacer film over at least the hardmask line pattern, 8) etching the spacer film, wherein after the etching a plurality of spacer lines are formed at the sidewalls of the hardmask line pattern, wherein each of the spacer lines have a line width approximately equal to the second line width, 9) removing the hardmask, 10) cropping rounded spacer connects using a photolithography technique—in the same step and/or process, portions of the spacer line pattern may also be cropped to create features such as line cuts, single or double line removal etc, depending on the pattern desired, 11) introducing features in the spacer line pattern using a photolithography technique, and 12) etching the substrate, wherein after the etching a plurality of lines are formed in the substrate.

A method for providing regular line patterns using interference lithography and sidewall patterning techniques is provided according to another embodiment. The method may include any of the following, in any order: 1) providing a plurality of regularly spaced parallel lines on a template using interference lithography, wherein the template, for example, a hardmask layer and/or advanced patterning film, is provided on a substrate, 2) depositing sidewalls on at least both longitudinal sides of the plurality of regularly spaced parallel lines, 3) removing the plurality of regularly spaced parallel lines, wherein after removal of the plurality of regularly spaced parallel lines a plurality of sidewall lines are left on the substrate, 4) deposit a gap filling material and then etch back to expose the sidewall lines, 5) removing the sidewall lines, wherein after removal of the plurality of regularly spaced sidewall lines a plurality of regularly spaced lines composed of the gap filling material are left on the substrate, and 6) cropping the plurality of lines composed of the gap filling material.

Providing a plurality of regularly spaced parallel lines on a template using interference lithography may include any of the following steps in any order: 1) exposing a plurality of regularly spaced parallel lines on a photoresist layer using interference lithography, 2) developing the photoresist layer to create a plurality of regularly spaced parallel lines in the photoresist, 3) trimming each of the plurality of regularly spaced parallel lines such that the ratio of line width to line spacing is about 33%, 4) etching the template to form a plurality of regularly spaced parallel lines in the template, and 5) removing the photoresist layer from the template. The interference lithography techniques may use any type of layer system and/or may include immersion techniques.

A method for providing printed line widths with a half pitch below 22 nm on a substrate is provided according to another embodiment. A plurality of regularly spaced printed lines may be provided and/or produced on a template, for example, a hardmask and/or advanced patterning film, with a half pitch below 44 nm using interference lithography techniques. Spacer may then be applied on the longitudinal sides of the plurality of printed lines on the template. The spacers may have a half pitch below 22 nm. After the spacers have been applied, the plurality of printed lines may be removed from the template. The template may also be exposed in another step using a photolithography mask. The mask exposes the rounded spacer connects formed at the lateral ends of the printed lines during spacer application. The spacers may then be etched to remove the rounder spacer connects. The substrate may then be etched.

Further areas of applicability of the present disclosure will become apparent from the detailed description provided hereinafter. It should be understood that the detailed description and specific examples, while indicating various embodiments, are intended for purposes of illustration only and do not limit the scope of the disclosure.

### BRIEF DESCRIPTION OF THE DRAWINGS

FIG. 1 shows a block diagram of an interference lithography system according to embodiments of the invention.

FIGS. 2A-2G show a process flow for creating regular line patterns using interference lithography and self-aligned double patterning on a positive tone according to one embodiment.

FIGS. 3A-3H show a process flow for creating regular line patterns using interference lithography and self-aligned double patterning on a negative tone according to one embodiment.

FIGS. 4A-4F shows another process flow creating regular line patterns using interference lithography and self-aligned double patterning on a positive tone according to one embodiment.

FIG. 5A shows a side view of a line pattern SEM image of a spacer deposited with CVD on an APF template according to one embodiment.

FIG. 5B shows a side view of a line pattern SEM image after a space etch and with the APF stripped out according to one embodiment.

FIG. 5C shows a side view of a line pattern SEM image after the hardmask etch according to one embodiment.

FIG. 5D shows a top SEM view of a line pattern formed with interference lithography and self aligned double patterning according to one embodiment.

FIG. 5E shows a SEM view of a line pattern formed with interference lithography and self aligned double patterning according to one embodiment.

FIG. 6A shows a top view of rounded spacer connects connecting printed lines resulting from an interference lithography and self-aligned double patterning according to one embodiment.

FIG. 6B shows a top view of printed lines with the rounded spacer connects removed according to one embodiment.

FIG. 7 shows a flowchart of a method for using combined interference lithography and self-aligned double patterning according to one embodiment.

FIG. 8 shows another flowchart of a method for using combined interference lithography and self-aligned double patterning on a negative tone according to one embodiment.

FIGS. 9A-9G show top views of a process flow for creating regular line patterns using interference lithography and self-aligned double patterning according to one embodiment.

FIG. 10 shows another flowchart of a method for using combined interference lithography, self-aligned double patterning, and photolithography according to one embodiment.

FIG. 11 shows another flowchart of a method for using combined interference lithography, self-aligned double patterning, e-beam lithography according to one embodiment.

FIG. 12 shows a simplified elevation view of an exemplary e-beam treatment apparatus that may be used to implement embodiments of the disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

The ensuing description provides preferred exemplary embodiment(s) only, and is not intended to limit the scope, applicability or configuration of the disclosure. Rather, the ensuing description of the preferred exemplary embodiment(s) will provide those skilled in the art with an enabling description for implementing a preferred exemplary embodiment. It should be understood that various changes may be made in the function and arrangement of elements without departing from the spirit and scope as set forth in the appended claims.

In one embodiment, the present disclosure provides for a lithographic scheme that may provide regular line patterning with resolutions around 11 to 15 nm half pitch. Such a scheme may employ interference lithography techniques to provide a line pattern having a resolution around 22 to 30 nm half pitch using a light source operating at 157 nm in a high index immersion. Self-aligned double patterning techniques may then be used to double the density of this line pattern and provide a line pattern with a resolution around 11 to 15 nm half pitch. During self-aligned double patterning steps/procedures a lithographic exposure and/or etch may occur to remove connected adjacent lines. During this lithographic exposure and/or etch various other features may be exposed and/or etched according to various embodiments. For example, cuts in the lines may be obtained.

Interference Lithography

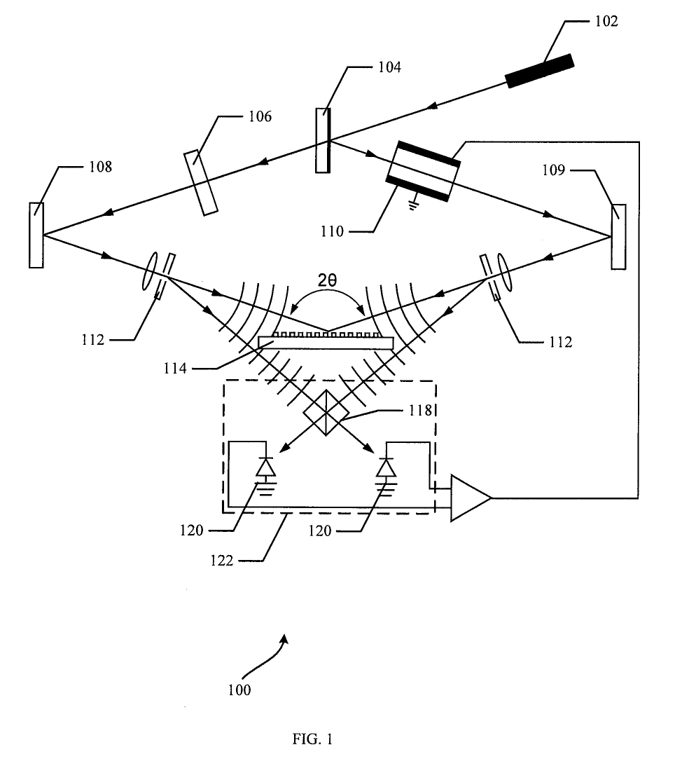

FIG. 1 shows a block diagram of an interference lithography system 100 according to one embodiment. A laser 102 produces a coherent light beam that is split at a beam splitter 104 into two beams. The laser 102, for example, may comprise an excimer laser. Various other light sources may also be used, for example LEDs broadband sources with a filter, etc. Other light sources may include UV light source from gas-charged lamps such as Hg-lamp at g-line (436 nm) and i-line (365 nm), or EUV light sources at 13.5 nm wavelength from a magnetron or Tin plasma. A slit may be used in conjunction with some of these light sources in order to add the coherence to the system and produce a line pattern.

Excimer lasers may produce light at various ultraviolet wavelengths. For example, an excimer laser may include an Ar₂ laser producing light with a wavelength of 126 nm, a Kr₂ laser producing light with a wavelength of 146 nm, an F₂ laser producing light with a wavelength of 157 nm, an Xe₂ laser producing light with a wavelength of 172 or 175 nm, an ArF laser producing light with a wavelength of 193 nm, a KrF laser producing light with a wavelength of 248 nm, an XeBr laser producing light with a wavelength of 282 nm, an XeCl laser producing light with a wavelength of 308 nm, an XeF laser producing light with a wavelength of 351 nm, a CaF₂ laser producing light with a wavelength of 193 nm, a KrC; laser producing light with a wavelength of 222 nm, a Cl₂ laser producing light with a wavelength of 259 nm, or a N₂ laser producing light with a wavelength of 337 nm. Various other lasers operating in other spectral bands may also be used with deviating from the scope of the present invention. The various embodiments of the invention will be described using an ArF excimer laser that produces light at 193 nm.

The two beams created at the beam splitter 104 are reflected toward a target 114 using two mirrors 108, 109. Absent a substrate or other material, the target 114 may be a process chuck. The target may hold a substrate or other material. The beam splitter 104, may include any light splitting element, such as a prism or diffraction grating. The two beams interfere constructively and destructively at the target 114 creating an interference pattern at the target 114. The position of the interference pattern may depends on the phase difference of the two beams. The angle θ is the angle of incidence of a single beam with respect to the normal of the target 114. The angle 2θ is the angle between the two beams at the substrate.

Spatial filters 112 may be included along each beam path. These spatial filters 112 may expand the beams for dose uniformity over a large area. Moreover, the spatial filters 112 may be used to remove spatial-frequency noise from the beams. Due to the potential of relatively long propagation distances (˜1 m) and the lack of additional optics after the spatial filer, the beams interfering at the substrate can be accurately approximated as spherical. Other optical elements may be employed throughout the optical paths of the two beams of light.

The spatial position of the interference fringes is determined by the relative phase of the beams, which makes this type of interferometer extremely sensitive to path length differences between the two arms. For this reason, a phase difference sensor 122 may be employed in conjunction with a Pockels cell 110 in one arm of the interference lithography system 100. The phase difference sensor 122 may include another beam splitter 118 and two photodiodes 120. Differential changes in the intensity on the photodiodes 120 may be converted into phase differences. The phase difference may then be adjusted at the Pockels cell 110. A variable attenuator 106 in the arm that does not have the Pockels cell 110 may be employed to balance any power lost through the Pockels cell 110.

The Pockels cell 110 may include any device that includes a photo refractive electro-optic crystal and/or a piezoelectric element that can change the polarization and/or phase of a light beam in response to an applied voltage. The phase may be changed by varying the index of refraction of the Pockels cell in response to the applied voltage. When a voltage is applied to this crystal it can change the phase of the light beam. In some Pockels cells, the voltage, V, required to induce a specific phase change, φ, can be calculated, for example, by the following equation:

$$V = \frac{φ}{π} {V}_{\frac{λ}{2}} ,$$

where

$${V}_{\frac{λ}{2}}$$

is the half wavelength voltage, which depends on the wavelength, λ, of the light beam passing through the Pockels cell. The Pockels cell may comprise, for example, an oxide of bismuth and germanium or of bismuth and silicon. Most importantly, the Pockels cell may include any device or material that may tune the phase of light in the presence of an applied voltage.

The Pockels cell may be replaced with an optical element that varies the optical path distance through the optical element. The optical path distance through the optical element may be change by rotating the optical element or by flexing the width of the optical element. The optical path distance may change using a mechanical devices or piezoelectrics. To induce a 180° phase change, for example, the optical element should increase the optical path distance by:

$$d = \frac{λ}{2 n} ,$$

where n is the index of refraction of the optical element. Accordingly, change in distance by either rotating the optical element or flexing is a fraction of the wavelength of the light beam passing through the optical element.

The Pockels cell may be used to align the phases of the two light beams within the interferometer as well as to adjust the phase difference between the two light beams so that they are 180° out of phase.

Interference Lithography Combined with Self Aligned Double Patterning

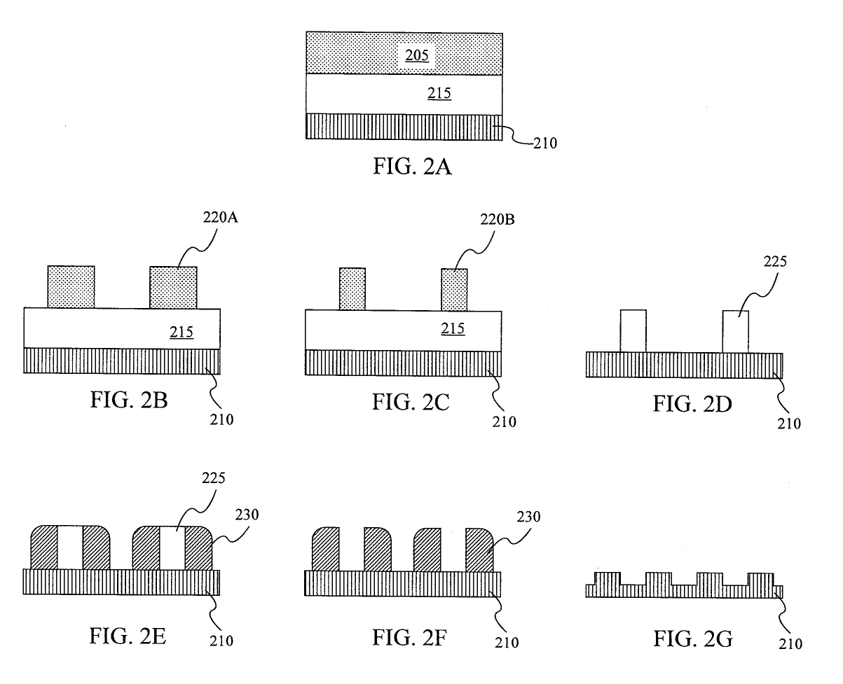

Self aligned double patterning (SADP) involves various techniques that use sidewall spacers to create hardmasks or photoresists as a means of doubling the printed line density. SADP may also be commonly referred to as sidewall patterning. An IL line pattern on a hardmask may be used as the starting point for creating a high density pattern using SADP according to various embodiments. FIGS. 2A-2G demonstrate the process flow of an exemplary IL and SADP processes using a positive tone. FIG. 2A shows a photoresist layer 205 deposited on a template layer 215 that is over a substrate 210. Using, for example, IL techniques, lines 220A may be created in the photoresist as shown in FIG. 2B. While only two lines 220A are shown, these lines may be part of a larger line pattern.

Following exposure and/or development of the lines 220A, the lines 220A may be trimmed as shown in FIG. 2C. These trimmed lines 220B, may be trimmed using any etching technique, for example, using dry etching. The trimmed lines 220B may trimmed such that the line width to line spacing ratio is about 1:3. Template lines 225 may be formed as shown in FIG. 2D. The template lines 225 may be formed during another etch step. The template may be comprised of a material that may be selectively etched. The trimmed lines 220B may also be removed during the etching step or during another step.

Following the template etch, spacers 230 may be formed around the template lines 225 as shown in FIG. 2E according to one embodiment. The spacers 230 may be formed, for example, by depositing a film over the template lines and etching and/or trimming the film until the spacers 230 have reached the appropriate dimension. Various other techniques may also be used to produce the spacers 230. The width of the spacers 230 may be about the same width as the width of the template lines 225. This width may, for example, be measured at the base of spacer 230, that is, where the spacer 230 contacts the substrate 210.

FIG. 2F shows a substrate 210 with spacers 230 and without the template lines 225. The template lines 225, for example, may be stripped. Accordingly, in some embodiments it may be a requirement that the template material may be easily removable after spacer 230 formation. Various etching techniques may be used to strip the template lines 225. For example, the template lines 225 may be etched using an O₂ ash technique. Using the spacers 230, the substrate 210 may be etched according to the spacer 230 pattern as shown in FIG. 2G. The spacers may then be removed, following the etching.

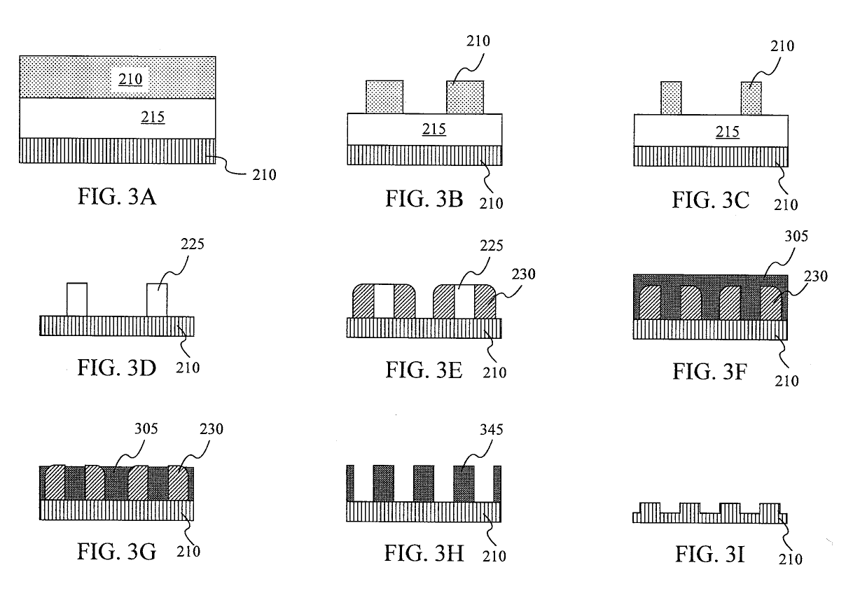

FIGS. 3A-3H demonstrate the process flow of an exemplary IL and SADP processes using a negative tone. FIGS. 3A-3E are similar to those shown in FIGS. 2A-2E, respectively. Similar processes may be followed to produce spacers 230 and template lines 225 on a substrate 210. The template lines may be stripped as shown in FIG. 2F, and as described in association therewith. A gap fill material 305 may then be deposited filling the gaps between the spacers as shown in FIG. 3F. The gap fill material 305 and spacers 230 may then be polished or trimmed as shown in FIG. 3G. Following which, the spacers 230 may be removed as shown in FIG. 3H, leaving a line pattern 345 in the gap fill material 305. The spacers may be removed, for example, using an etching process that is selective in that it does not remove the gap fill material 305. The resulting line pattern 345 in the gap fill material may then be used to create a line pattern in the substrate 210. The gap fill material may then be removed.

While embodiments have been described that provide a regular line pattern in a substrate, there are many variations to these embodiments that may be used without deviating from the spirit and scope of the invention. For example, additional layers, etchings, and/or depositions may be used throughout the process. Moreover, various changes in the material composition may also be employed.

According to one embodiment, the spacers 230 may be comprised of a material with good step coverage, conformality, hardmask properties, and/or etch selectivity against the template during the template strip process. According to another embodiment, a bottom hardmask layer may also be used between the spacer/template layer 230/215 and the substrate layer 210. The bottom hardmask can serve to supplement the spacer when patterning the substrate.

In some embodiments, the spacer 230 alone is not sufficient to complete the substrate 210 etch due to the limited height and faceted shape of the spacer 230. The height of the spacer 230 is limited by the pattern collapse, the line bending issues for the template and free-standing spacer, and/or the aspect ratio capabilities of the spacer deposition process. Because the spacer etch process leaves the top of the spacer 230 as a faceted half-dome, this limits the usable height of the spacer as a hardmask, as well as leads to accelerated erosion in high bias etch processes. Accordingly, a bottom hardmask layer may be used. For example, an aspect ratio between 4:1-4.5:1 (height:width) for the spacer may provide good results. According to one embodiment, the bottom hardmask may comprise a chemical vapor deposition (CVD) carbon hardmask, for example, an advance patterning film™ (APF). In some embodiments, APF may be used because it is easily etched with extremely high selectivity to most spacer materials, such as oxides and/or nitrides, and high selectivity to most device materials, such as oxides, nitrides, tungsten, and/or polys. This may allow one to extend the amount of device etching which may simplify eventual hardmask removal with an O₂ plasma ash.

According to embodiments, the spacer 230 may comprise oxides and nitrides. For example, ozonated TEOS or plasma enhanced CVD techniques may be used. According to embodiments, the template layer 215 may comprise materials that are easily stripped, for example, a dry stripe, with selectivity to the spacer material. For example, the template layer 215 may comprise APF, which, for example, may be stripped with high selectivity to silicon, oxide and nitride families. As another example, the template layer 215 may comprise a silicon material which may be stripped using dry silicon recess etch techniques that are also highly selective to oxides and nitrides.

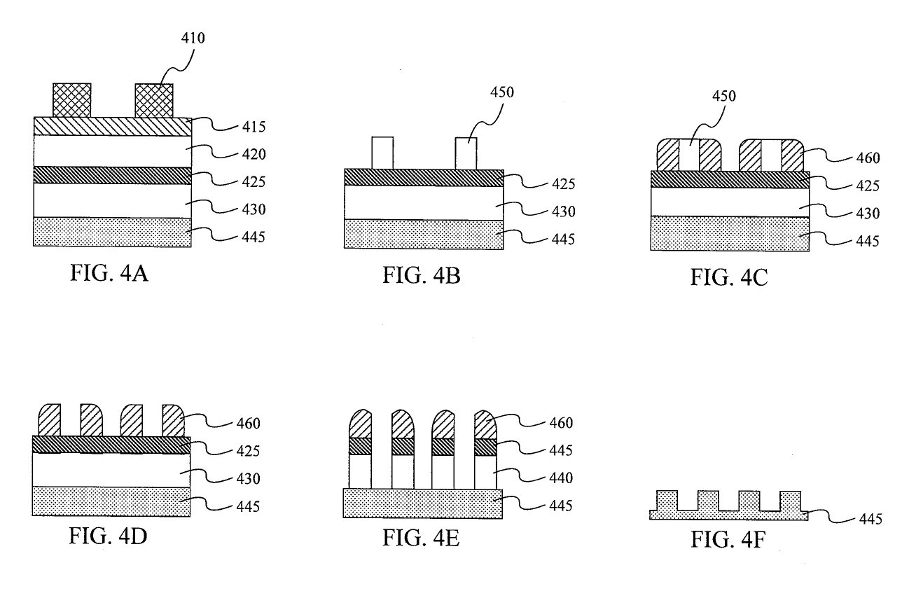

FIGS. 4A-4F shows another process flow creating regular line patterns using interference lithography and self-aligned double patterning on a positive tone according to another embodiment. A patterning film stack is shown in FIG. 4A with a substrate 445 as the base layer. The substrate, for example, may comprise silicon. A first hardmask layer 430 is deposited on the substrate 445. The first hardmask layer, for example may comprise a CVD amorphous carbon hardmask, such as, APF. A cap 425 is deposited on the first hardmask layer 430. The cap 425 may comprise a nitride and/or silicon. A second hardmask layer 420 is provided on the cap 425. The second hardmask layer 420 may also comprise a CVD amorphous carbon, such as APF, and may be uses as a sacrificial template. A dielectric cap 415 may be deposited on the second hardmask and may comprise an oxide or a nitride. While the first and second hardmask layers are shown as comprising the same material, they may be comprised of completely different materials. The top layer includes a photoresist layer with a line pattern 410.

FIG. 4A shows a line pattern 410 in the top layer. The line pattern 410 may be created using IL techniques. In one embodiment, IL may employ a liquid immersion tool. Various density of lines and spaces may be used, without limitation. For example, the line density may be 45 nm, 30 nm or 22 nm, depending on the IL tool used.

The line pattern 410 in the first hardmask layer may be trimmed as shown in FIG. 4B. The resulting trimmed lines 450 may have a line to space ratio of approximately 33%. The line to space ratio may vary. In some embodiments, the line to space ratio may be about 30%, 31%, 32%, 34%, 35%, or 36%. Accordingly, according to one example, if a line pattern 410 with a line width and line spacing of 40 nm was provided using IL, after the trim the resulting trimmed lines would be about 20 nm with line spacing of 60 nm.

FIG. 4C shows a spacer 460 is added to each sidewall of the trimmed lines 450. For example, if the trimmed line widths are 20 nm, each spacer may also have a 20 nm width. The lines 450 in the second hardmask layer 420 may then be removed using, for example, an oxygen ash process without a wet clean as shown in FIG. 4D. The spacers may then be used as a hardmask to transfer the pattern into the first hardmask layer 430 as shown in FIG. 4E, which may then be used to etch the final pattern into the substrate.

Because APF is a widely adopted hardmask for most dielectrics and conductors used in the semiconductor industry, using IL and SADP on APF layers could be applied universally to any desired substrate material.

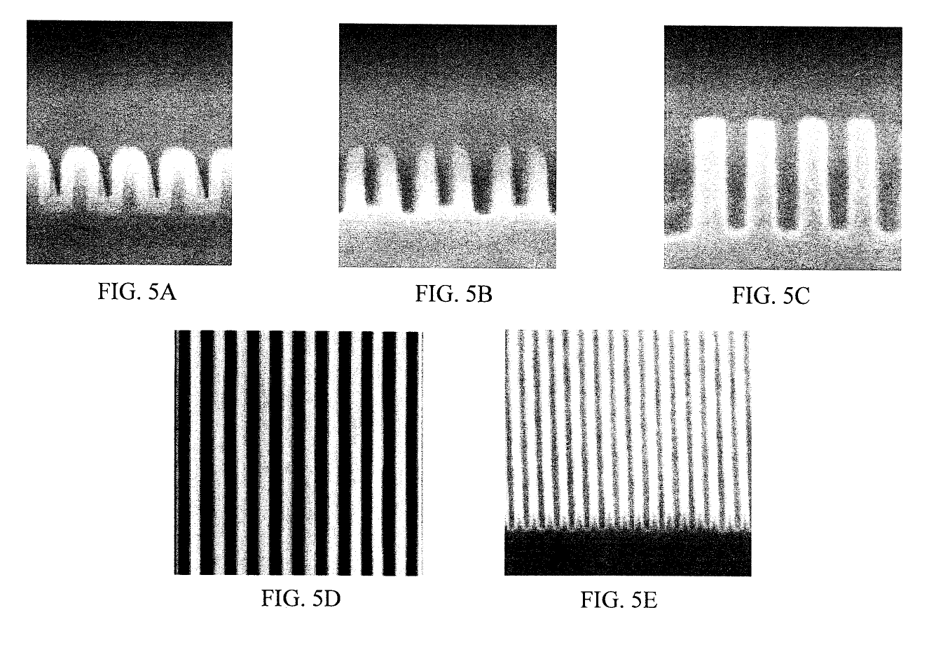

FIGS. 5A-5E show various scanning electron microscope (SEM) snapshots of processes flows using IL and SADP according to embodiments. FIG. 5A shows a side view of a line pattern SEM image of a spacer deposited with CVD on an APF template. FIG. 5B shows a side view of a line pattern SEM image after a space etch and with the APF stripped out. FIG. 5C shows a side view of a line pattern SEM image after the hardmask etch. FIG. 5D shows a top SEM view of a line pattern formed with interference lithography and self aligned double patterning. FIG. 5E shows an SEM view of a line pattern formed with interference lithography and self aligned double patterning.

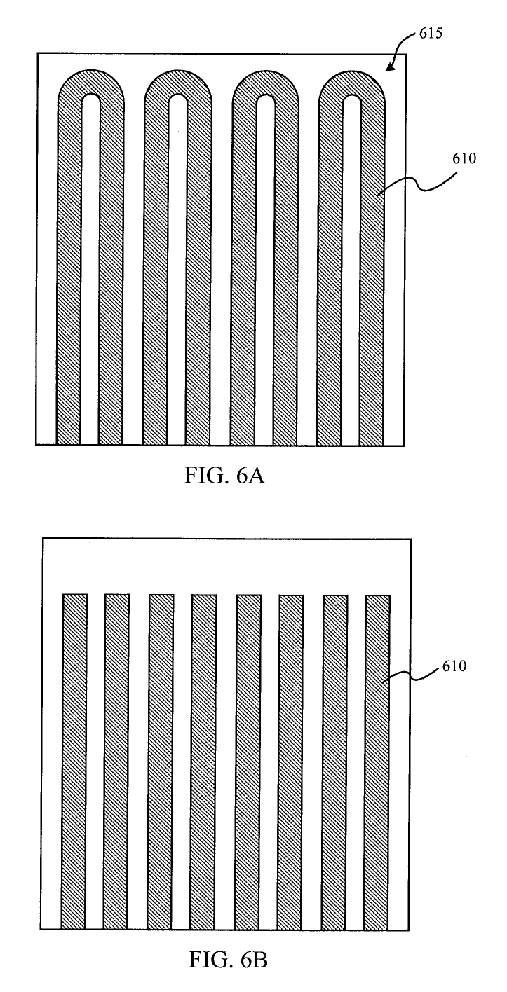

Spacer deposition not only results in spacers 610 along the side wall of a printed line, but also results in rounded spacer connects 615 around the ends of the printed line as shown in FIG. 6A. Accordingly, after the printed line is removed, the rounded spacer connects 615 may be cropped as shown in FIG. 6B. Removal of the rounded spacer connects 615 may be accomplished using lithography techniques, such as, for example, photolithography, E-beam lithography, IL, etc. As one example, a mask may be used in a photolithography step. The lithography step, depending on the tone of the spacer material, may expose the rounded spacer connects 615 or the spacer lines exclusive of the spacer connects 615. Following exposure, the rounded spacer connects may be etched away. More than one lithograph step may be used. Moreover, the lithography step may also add other features, such as, wide lines, pads, line connects, line trims, line cuts, etc.

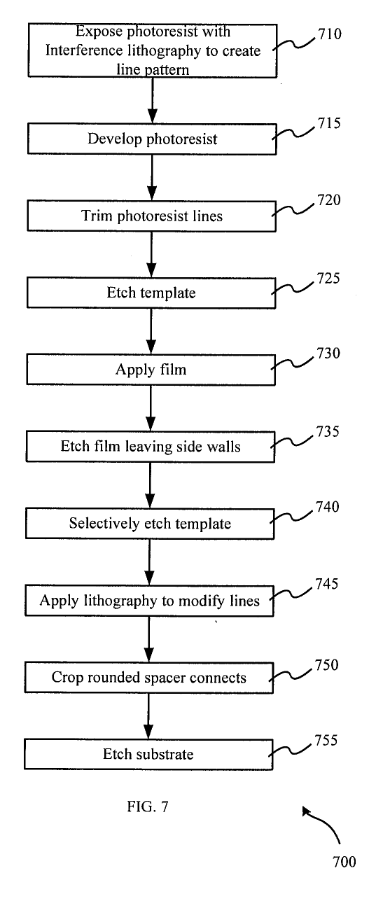

FIG. 7 shows a flowchart 700 of a method for using combined interference lithography and self-aligned double patterning in a positive tone process according to one embodiment. At block 710, a photoresist is exposed by IL to create a line pattern. The photoresist is developed to produce lines in the photoresists at block 715. At block 720, the lines are trimmed to a narrower line width to space width ratio. For example, the line width to space width ratio may be about 33%. A template layer beneath the photoresist, may then be etched to produce lines in the template at block 725. Blocks 715 and 720 may occur in any order. That is, the template may be etched and then trimmed according to another embodiment.

Once the template has an array of lines, a film may be deposited over the template at block 730. The film may be etched leaving spacers at the sidewalls of the template lines at block 735. The etching may provide spacers of nearly the same width as the template lines. Selective etching may then occur at block 740 removing the printed lines in the template. The spacer lines may be modified using various lithography techniques at block 745. For example, the spacer lines may be modified or cut. The rounded spacer connects may also be cropped at block 750. Blocks 745 and 750, according to embodiments, may occur using the same lithography step and/or process. The line pattern from the spacers may then be etched into the substrate at block 755. Various intermediary steps may be included in the flowchart 700 without limitation. For example, various deposition, etching, curing, annealing, etc. processes may occur between these steps. Moreover, the steps may occur in any order and some steps may be omitted.

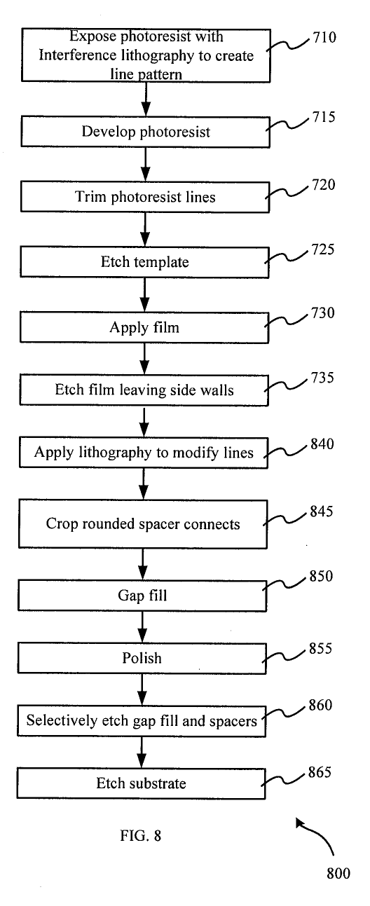

FIG. 8 shows another flowchart 800 of a method for using combined interference lithography and self-aligned double patterning as a negative tone according to one embodiment. Blocks 710, 715, 720, 725, 730, and 735 are similar to those shown and described in accordance with FIG. 7. Once the spacers have been placed and the template line pattern removed, the resulting line pattern may be modified using any lithography technique at block 840. The rounded spacer connects may be cropped at block 845. Blocks 840 and 845 may occur using the same lithography step and/or process. Gaps may be filled with a deposition process as shown in block 850. At block 855, the spacers and gap fill material may be polished to expose the spacers. The spacers may be removed by selective etching at block 860. Following which, the substrate may be etched at block 865.

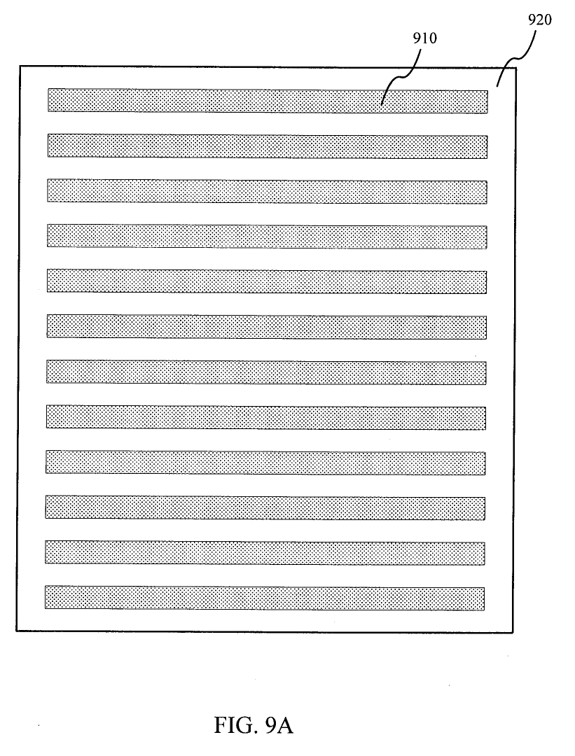

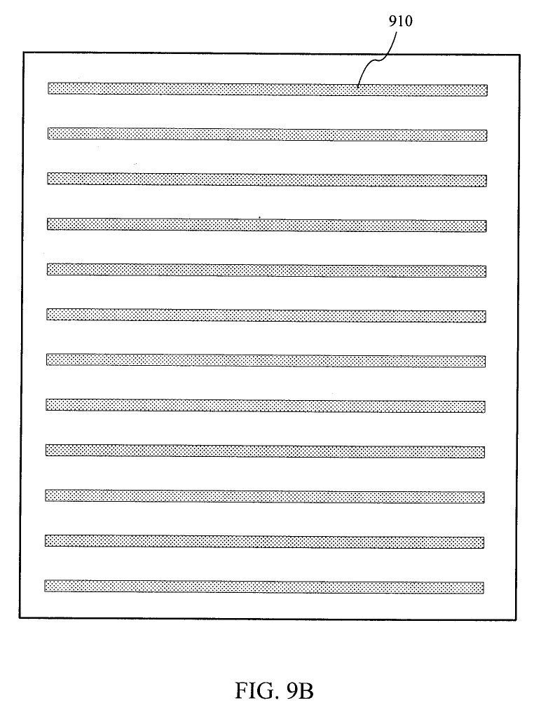

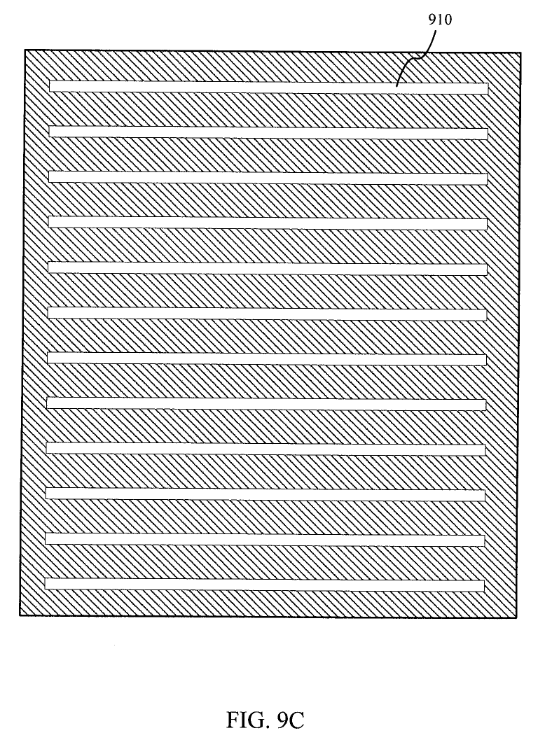

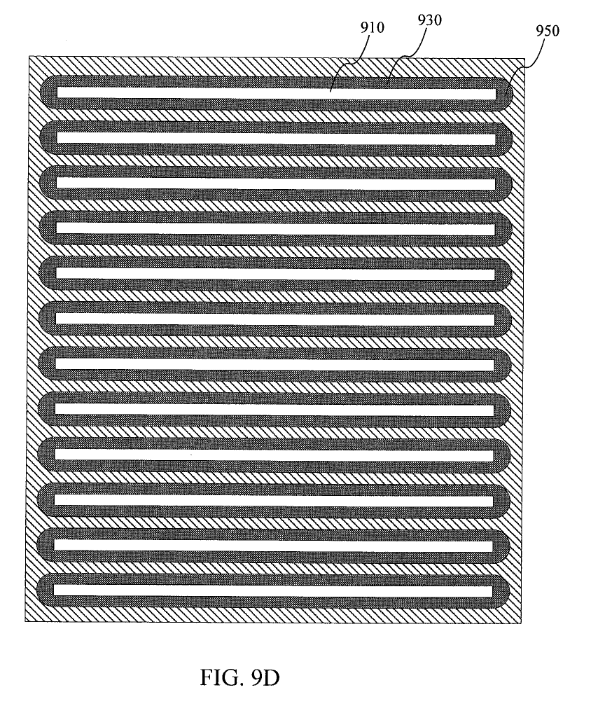

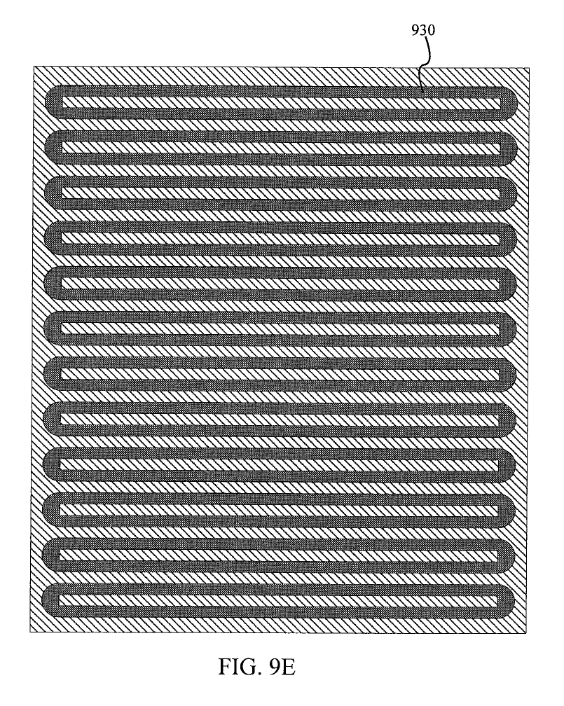

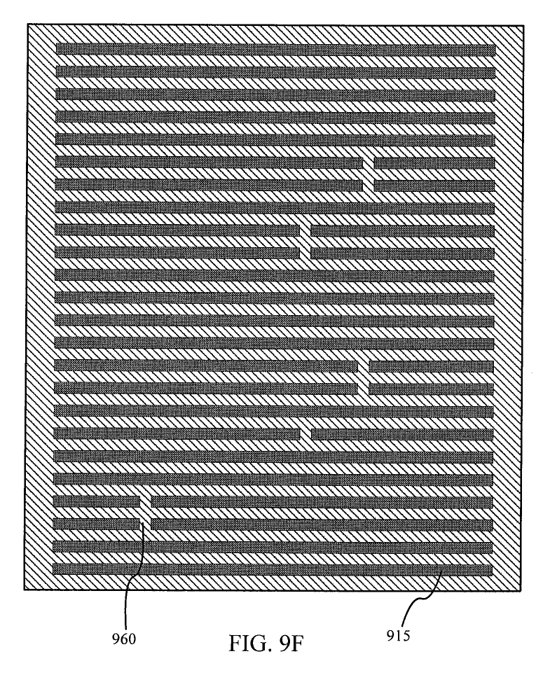

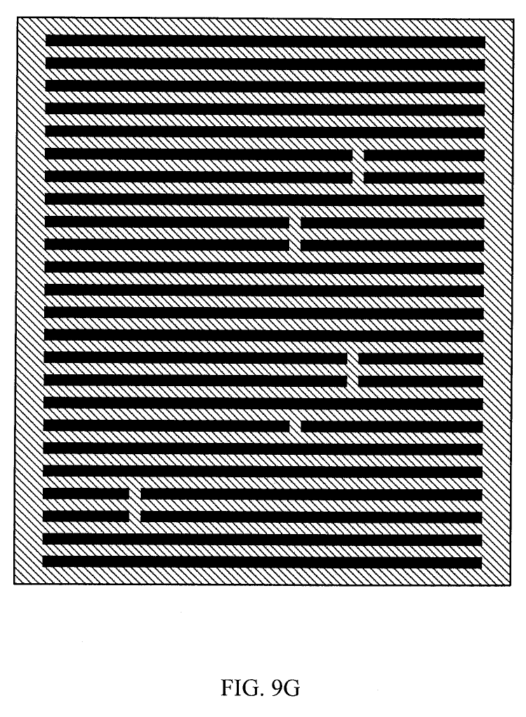

FIGS. 9A-9G show top views of a process flow for creating regular line patterns using interference lithography and self-aligned double patterning according to one embodiment. FIG. 9A shows an exemplary line pattern 910 array created using interference lithography. The lines are created, for example, within a photoresist layer on a template layer 920. FIG. 9B shows the line pattern 910 after trimming. Note, the line space to line width ratio is approximately 3:1. FIG. 9C shows the line pattern 910 etched into the template layer. FIG. 9D shows the spacers 930 created at the sidewalls of the line pattern 910. The figure also shows the rounded spacer connects 950. FIG. 9E shows the spacers 930 with the line pattern removed. A lithography process may be applied to remove the rounded spacer connects and may also be used to introduce various features in the spacer pattern. For example, cutouts 960 have been introduced in the spacer pattern 915. FIG. 9G shows the spacer pattern etched within the substrate.

Various embodiments of the invention may be used in the fabrication flash memory or Dynamic Random Access Memory (DRAM), processors, application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, etc. without limitation.

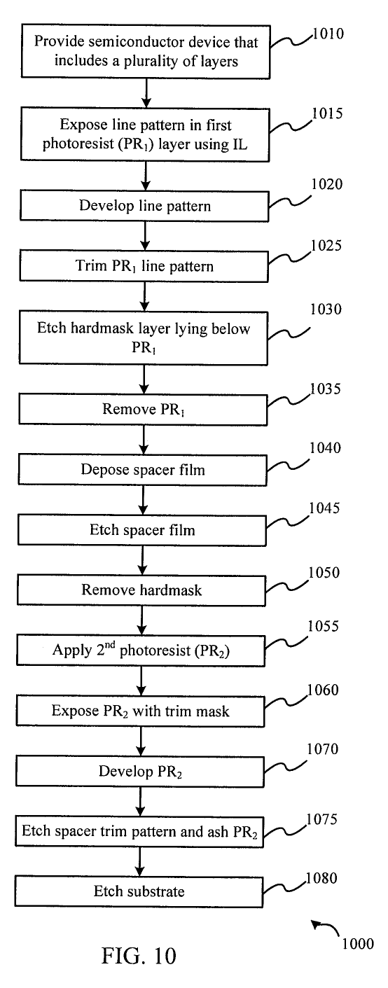

FIG. 10 shows another flowchart 1000 of a method for using combined interference lithography, self-aligned double patterning, and photolithography according to one embodiment. The method begins by providing a multi-layered semiconductor device at block 1010. The layers may be formed using various deposition techniques. The layers of the semiconductor device may include, for example, a substrate, template, hardmask, photoresist, etc. A line pattern may be exposed in a top most photoresist layer using interference lithography at block 1015. The line pattern may have a first line width and a first line spacing. The line pattern may be developed, at block 1020, using any development technique to form a photoresist line pattern on a hardmask layer below the photoresist layer. The photoresist line pattern may then be trimmed at block 1025. The resulting trimmed line pattern has a second line width that is narrower than the first width and a line spacing that is about one third the first line spacing. A hardmask layer lying below the photoresist layer may then be etched at block 1030, forming a lint pattern in the hardmask layer. The photoresist may then be removed at block 1035.

A spacer film may then be deposited over at least the hardmask line pattern at block 1040. This spacer film may then be etched at block 1045. After the etching a plurality of spacer lines are formed at the sidewalls of the hardmask line pattern. Each of the spacer lines have a line width approximately equal to the second line width and the etching results in rounded spacer connects. The hardmask may then be removed at block 1050. A second photoresist may be applied and exposed using a trim mask at blocks 1055, 1060. The trim mask may be used to crop rounded spacer connects and/or provide line features in the lines. The photoresist may then be developed at block 1070. The spacer pattern may then be etched to crop rounded spacer connects and/or provide line features in the spacer lines, using the photoresist as an etch mask, and the photoresist may then be removed by, for example, an ashing process at blocks 1075. Finally the substrate is etched leaving a plurality of lines and/or line features at block 1080.

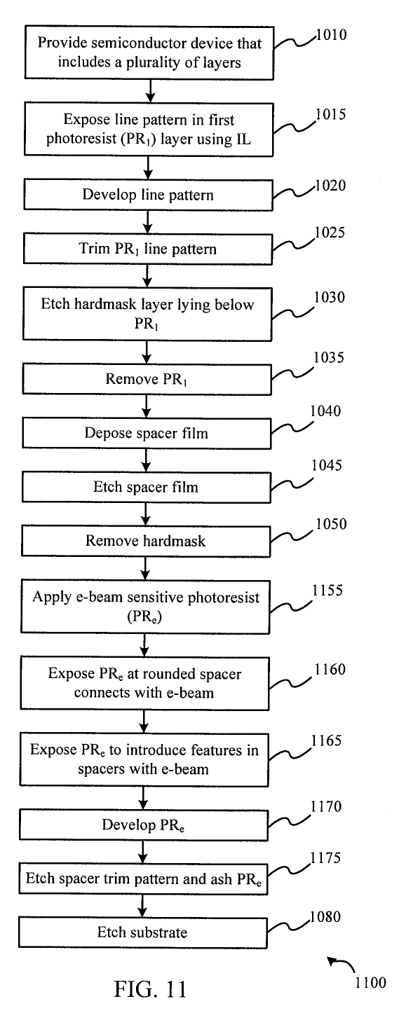

FIG. 11 shows another flowchart of a method for using combined interference lithography, self-aligned double patterning, e-beam lithography according to one embodiment. Block 1010 through block 1050 are similar to those described above in regard to FIG. 10. After the hardmask is removed at block 1050, an e-beam sensitive photoresist is applied at block 1155. The e-beam sensitive photoresist may be applied using any deposition technique. The e-beam sensitive photoresist may comprise, for example, a polymer dissolved in a liquid solvent which may be applied by spin coating. The e-beam sensitive photoresist may comprise, for example, Polymethyl methacrylate (PMMA), EBR-9, Poly(butene-1-sulfone), ZEP-520, COPm, Shipley SAL resist, P(SI-CMS), etc. The photoresist may also comprise a multilayer resist. The rounded spacer connects may then be exposed using an e-beam at block 1160. At block 1165 features may be exposed in the line pattern using an e-beam. The photoresist may then be developed at block 1170. The spacer pattern may then be etched to crop rounded spacer connects and/or provide line features in the spacer lines, using the e-beam photoresist as an etch mask, and the e-beam photoresist may then be ashed at block 1175. Finally the substrate is etched leaving a plurality of lines and/or line features at block 1080.

E-Beam Lithography

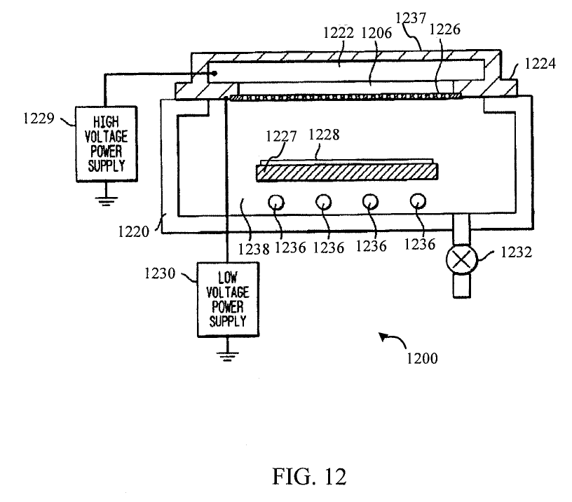

FIG. 12 shows a simplified elevation view of an exemplary e-beam treatment apparatus that may be used to implement embodiments of the disclosure. The following disclosure relating to an e-beam treatment apparatus is exemplary only. Any e-beam treatment apparatus may be used, for example, a modified scanning tunneling microscope or any other e-beam technology, without limitation. Moreover, any other lithography system may be used as part of the embodiments of this disclosure. Descriptions related to e-beam are presented only as an example of one mask-less lithography processes. The e-beam treatment apparatus 1200 includes vacuum chamber 1220, large-area cathode 1222, target or substrate 1227 that is located in field-free region 1238, and grid anode 1226 placed between target 1227 and cathode 1222 at a distance from cathode 1222 that is less than the mean free path length of electrons emitted therefrom. The substrate may include a to-be-treated film 1228 deposited on target or substrate 1227, such as an e-beam sensitive photoresist. The grid anode 1226 may include, for example, a fine mesh screen.

The e-beam treatment apparatus 1200 may further include a high voltage insulator 1224 which isolates grid anode 1226 from the large-area cathode 1222, a cathode cover insulator 1237 located outside vacuum chamber 1220, a variable leak valve 1232 for controlling pressure inside vacuum chamber 1220, a variable high voltage power supply 1229 connected to large-area cathode 1222, and a variable low voltage power supply 1230 connected to grid anode 1226. The variable low voltage power supply 1230 may vary, for example, and without limitation, from about 0 to about 100 volts. Quartz lamp(s) irradiate the bottom side of substrate 1227 to provide, for example, heating independent of that provided by the electron beam.

In accordance with further embodiments of the present invention, instead of utilizing lamp heating, the wafer or substrate may be disposed on a body that is referred to as a chuck or susceptor. In accordance with such embodiments, the chuck may be resistively heated in a manner that is well known to those of ordinary skill in the art to provide heating independent of that provided by the electron beam. In addition, the chuck may be an electrostatic check (for example, a monopolar or bipolar electrostatic chuck) to provide good contact between the wafer and the chuck. Many methods are well known to those of ordinary skill in the art for fabricating such electrostatic chucks. Further in accordance with such embodiments, a backside gas may be flown between the wafer and the chuck to enhance thermal conductivity between the two in a manner that is well known to those of ordinary skill in the art, such backside gas being flown in one or more zones depending on the need for controlling temperature uniformity. Still further in accordance with such embodiments, a cooling liquid may be flown inside the chuck to be able, for some treatment mechanisms, to reduce the temperature of the wafer in light of heating provided by the electron beam. Many methods are well known to those of ordinary skill in the art for flowing a cooling liquid through a chuck.

In operation, the substrate 1227 is placed in vacuum chamber 1220, and vacuum chamber 1220 is pumped to a pressure in a range of, for example, and without limitation, from about 1 to about 200 mTorr. The exact pressure is controlled by variable rate leak valve 1232 which is capable of controlling pressure, for example, and without limitation to about .±0.1 mTorr. A high voltage (for example, a negative voltage between, for example, and without limitation, about −500 volts and about −30,000 volts or higher) at which the treatment is to take place is applied to large-area cathode 1222 by high voltage power supply 1229. Variable voltage source 1230 (for example: a d.c. power supply capable of sourcing or sinking current) is also applied to grid anode 1226. The voltage on grid anode 1226 is utilized to control electron emission from large-area cathode 1222.

To initiate electron emission, gas in a space between large-area cathode 1222 and target 1227 must become ionized. This occurs as a result of naturally occurring gamma rays, or emission can instead be initiated artificially inside vacuum chamber 1220 by a high voltage spark gap. Once this initial ionization takes place, positive ions are attracted to grid anode 1226 by a slightly negative voltage (for example, and without limitation, from about 0 to about −80 volts) being applied to grid anode 1226. These positive ions pass into accelerating field region 1206 between large-area cathode 1222 and grid anode 1226, and are accelerated towards large-area cathode surface 1222 as a result of the high voltage applied to large-area cathode 1222. Upon striking the surface of the large-area cathode 1222, these high energy ions produce secondary electrons that are accelerated back toward grid anode 1226. Some of these electrons (which are now traveling mostly perpendicular to the cathode surface) strike grid (anode) structure 1226, but may pass through grid anode 1226 and continue on to target 1227. These high energy electrons ionize gas molecules in a space between grid anode 1226 and target 1227.

Grid anode 1226 is placed at a distance less than the mean free path of electrons emitted by large-area cathode 1222. As a result, no significant ionization takes place in accelerating field region 1206 between grid anode 1226 and large-area cathode 1222. In addition, ions created outside grid anode 1226 are controlled (repelled or attracted) by voltage applied to grid anode 1226. Thus, emission (i.e., electron beam current) can be continuously controlled (from very small currents to very large currents) by varying the voltage on grid anode 1226. Alternatively, electron emission can be controlled by use of variable leak valve 1232 which can raise or lower the number of molecules in the ionization region between target 1227 and large-area cathode 1222. However, due to a relatively slow response time of adjusting pressure in vacuum chamber 1220, it is netter to adjust the pressure initially to produce a nominal emission current, and then utilize bias voltage on grid anode 1226 to control emission current.

Electron emission can be turned off entirely by applying a positive voltage to grid anode 1226 wherein the positive grid voltage exceeds the energy of any of the positive ion species created in the space between grid anode 1226 and target 1227.

Even though the grid-to-cathode gap must be less than the mean free path determined by the lowest desired operating accelerating voltage, treatment apparatus 100 is operated at a vacuum level where the breakdown strength of the vacuum exceeds the field created by the highest operating voltage applied across the selected grid-to-cathode spacing. This low or soft vacuum level enables cathode 1222 and target 1227 to be placed in close proximity to each other in the same vacuum environment.

Electrons emitted from large-area cathode 1222 are accelerated to grid anode 1226, and are mostly traveling perpendicular to the surface of grid anode 1226 and large-area cathode 1222. Some emitted electrons are intercepted by grid anode 1226 and some are scattered by grid anode 1226. If target 1227 is within a few millimeters of grid anode 1226, electrons will cast an image of grid anode 1226 on target 1227. However, if target 1227 is placed at a large distance, such as, for example, and without limitation, a distance in a range from about 10 to about 20 centimeters from grid anode 1226, the electron beam diffuses (due to initial transverse velocities and scattering) to a fairly uniform current density across the whole emitting area. The irradiation of target 1227 can be made even more uniform by sweeping the beam back and forth across target 1227 by means of a time-varying magnetic field produced by deflection coils surrounding vacuum chamber 1220. In a further embodiment, an aperture plate or mask is placed between grid anode 1226, and in contact or close proximity with target 1227. Since electrons moving toward target 1227 are nearly collimated by the accelerating field, and have relatively small transverse velocities, a shadow mask, placed in close proximity to target 1227 will be accurately replicated by the electron beam that passes through the mask or aperture plate. In a still further embodiment, a shaped aperture is placed between grid anode 1226 and target 1227. This aperture can form a small shaped electron beam having a uniform current density. Target material 1227 is then scanned or stepped under the beam to generate multiple patterns on the substrate or target. After exposing a feature of target 1227, target 1227 is moved, and a new exposure is undertaken.

In some applications, it may be desirable to provide a constant beam current at different electron beam energies. For example it may be desirable to expose or cure an upper layer of film 1228, but not a lower or bottom layer. This can be done by utilizing an electron beam energy low enough such that most of the electrons are absorbed in the upper layer of film 1228. Subsequent to treating the upper layer, it may be desirable to treat a deeper layer of film 1228. This can be done by raising the accelerating voltage of the electron beam to penetrate to the deeper layer. It would be desirable in performing these exposures to be able to alter the accelerating voltage without causing a change in the emission current. However, if the accelerating voltage is increased it tends to cause more ionization and therefore an increase in beam current. Similarly if the accelerating voltage is lowered, ionization lessens and the beam current is decreased. In accordance with one embodiment in which a constant beam current is maintained independent of changes in accelerating voltage, the beam current is sampled via a sensor. An output from the sensor is used to control voltage on grid anode 1226 such that an increase in beam current will cause a decrease in bias voltage on grid anode 1226 and a decrease in emission current from large-area cathode 1222. The output from the sensor is adjusted so that any change in current caused by a change in the accelerating voltage is counteracted by a change in bias voltage to maintain the beam current reaching the target constant. Alternatively, an output from the sensor can be connected to a voltage controlled variable rate leak valve to counteract changes in emission current by raising or lowering the pressure in ionization region 1238.

The depth to which impinging electrons penetrate a target layer before being absorbed depends on many factors (including the particular material which is being treated); one of the most critical of which is the energy of the electron beam as determined by the accelerating voltage. Impinging electrons penetrate the surface of the target relatively easily, and are absorbed principally at some depth below the surface (a peak depth). A lesser number of electrons is absorbed near the surface, and the density of absorbed electrons tapers off gradually to practically zero at a greater depth. As the beam energy (controlled by accelerating voltage) is increased, the peak is driven further from the surface. Thus, one may select a low electron accelerating voltage to expose a top layer of the target without exposing a deeper layer. Further, due to the nature of the electron beam scattering process the lower layer can be exposed to a higher level of electron treatment than the upper layer by selecting a sufficiently high incident beam energy. The total treatment by electrons at a selected level is controlled by the beam current and exposure time. In effect, control of dose and beam energy provides selective control of treatment at selected depths in the target.

In an application where film 1228 on substrate 1227 is an insulator, film 1228 may start to charge negatively under electron bombardment. However, positive ions near the substrate surface will be attracted to this negative charge and neutralize it. Thus, since any charge build up on the surface of the substrate is quickly neutralized by positive ions in the vicinity of the wafer surface, abeam treatment of insulating films may be carried out without requiring a conductive coating to drain off charge. In addition, it is believed that subsurface charge dissipation is achieved by e-beam induced conductivity. Also, it is further believed that the combination of large area electron beam irradiation, and raising the temperature of the treated film in applications where such is the case, increases the electron beam conductivity of insulation layers which dissipate charge build-up created by the impinging electron beam. This enables treatment without inducing electron traps or positive charge build-up in the layers. In addition, it is believed that the e-beam induced conductivity effect is dependent on substrate temperature (becoming more conductive with increasing temperature). This is then taken in to account in developing e-beam treatment recipes to ensure that one does not create static charge.

As shown in FIG. 12, lamps 1236 irradiate and heat wafer or substrate 1227, thereby controlling its temperature. Since wafer 1227 is in a vacuum environment, and is thermally isolated, wafer 1227 can be heated or cooled by radiation. If lamps 1236 are extinguished, wafer 1227 will radiate away its heat to the surrounding surfaces and gently cool. Wafer 1227 is simultaneously heated by lamps 1236 and irradiated by the electron beam throughout the entire process. For example, in accordance with one embodiment, infrared quartz lamps 1236 are on continuously until the temperature of wafer 1227 reaches a process operating temperature. Lamps 1236 are thereafter turned off and on at varying duty cycle to control the wafer temperature. Wafer 1227 and film 1228 are continually irradiated with electrons until a sufficient dose has accumulated, and film 1228 has been treated. Using this technique, thick layers can be cured in, for example, and without limitation, in less than ten minutes.

In accordance with further embodiments of the present invention, infrared lamps 1236 are not used to heat wafer 1227. In accordance with such embodiments, the electron beam is used to both irradiate and heat wafer 1227. In this case the product of the beam current and the beam voltage is greater than the power radiated away by the wafer, and therefore wafer 1227 is heated by the electron beam. In accordance with further embodiments of the present invention, wafer or substrate 1227 can be cooled using a cooled plate. This will keep wafer or substrate 1227 close to a predetermined temperature.

In accordance with one or more further embodiments of the present invention, large-area cathode 1222 is comprised of, or is coated with, one or more of Ti, Mo, and doped Si to provide enhanced secondary electron formation and reduced sputtering of large-area cathode 1222. In accordance with one or more still further embodiments of the present invention, grid anode 1226 is comprised of, or is coated with, one or more of Ti, Mo, and graphite to reduce an incubation period used to prepare the chamber for operation.

Process conditions for e-beam treatment include the following. The pressure in vacuum chamber 20 may vary in a range of from about 10⁻⁵ to about 10² Torr, and preferably in a range of from about 10⁻³ to 10⁻¹ Torr. The distance between substrate 1227 and grid anode 1226 should be sufficient for electrons to generate ions in their transit between grid anode 1226 and the surface of substrate 1227. The temperature of wafer 1227 may vary in a range from about 0° C. to about 1050° C. The electron beam energy may vary in a range from about 0.1 to about 100 KeV. The total dose of electrons may vary in a range from about 1 to about 100,000 μC/cm². The dose and energy selected will be proportional to the thickness of the films to be treated. The gas ambient in e-beam tool apparatus may be any of the following gases: nitrogen, oxygen, hydrogen, argon, helium, ammonia, silane, xenon or any combination of these gases. The electron beam current may vary in a range from about 0.1 to about 100 mA. Preferably, the e-beam treatment is conducted with a wide, large beam of electrons from a uniform large-area electron beam source which covers the surface area of the film to be treated. In addition, for thick films, the electron beam dose may be divided into steps of decreasing voltage which provides a uniform dose process in which the material is cured from the bottom up. Thus, the depth of electron beam penetration may be varied during the treatment process. The length of the treatment may range from about 0.5 minute to about 120 minutes As those of ordinary skill in the art can readily appreciate, the length of e-beam treatment may depend one or more of the above-identified parameters, and that particular sets of parameters can be determined routinely without undue experimentation in light of the detailed description presented herein.

Specific details are given in the above description to provide a thorough understanding of the embodiments. However, it is understood that the embodiments may be practiced without these specific details. For example, circuits, structures, and/or components may be shown in block diagrams in order not to obscure the embodiments in unnecessary detail. In other instances, well-known circuits, processes, algorithms, structures, components, and techniques may be shown without unnecessary detail in order to avoid obscuring the embodiments.

Also, it is noted that the embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be rearranged. A process is terminated when its operations are completed, but could have additional steps not included in the figure. A process may correspond to a method, a function, a procedure, a subroutine, a subprogram, etc. When a process corresponds to a function, its termination corresponds to a return of the function to the calling function or the main function.

Furthermore, embodiments may be implemented by hardware, software, scripting languages, firmware, middleware, microcode, hardware description languages and/or any combination thereof. When implemented in software, firmware, middleware, scripting language and/or microcode, the program code or code segments to perform the necessary tasks may be stored in a machine readable medium, such as a storage medium. A code segment or machine-executable instruction may represent a procedure, a function, a subprogram, a program, a routine, a subroutine, a module, a software package, a script, a class, or any combination of instructions, data structures and/or program statements. A code segment may be coupled to another code segment or a hardware circuit by passing and/or receiving information, data, arguments, parameters and/or memory contents. Information, arguments, parameters, data, etc. may be passed, forwarded, or transmitted via any suitable means including memory sharing, message passing, token passing, network transmission, etc.

While the principles of the disclosure have been described above in connection with specific apparatuses and methods this description is made only by way of example and not as limitation on the scope of the disclosure.

What is claimed is:

1. A method for providing regular line patterns using interference lithography and sidewall patterning techniques, the method comprising:
providing a plurality of regularly spaced parallel lines on a template using interference lithography, wherein the template is provided on a substrate;
depositing sidewalls on at least both longitudinal sides of the plurality of regularly spaced parallel lines;
removing the plurality of regularly spaced parallel lines, wherein after removal of the plurality of regularly spaced parallel lines a plurality of sidewall lines are left on the substrate;
etching portions of the substrate; and
removing the sidewall lines.

2. The method according to claim 1, wherein the template is a hardmask.

3. The method according to claim 1, wherein the providing a plurality of regularly spaced parallel lines on a template using interference lithography further comprises:
exposing a plurality of regularly spaced parallel lines on a photoresist layer using interference lithography;
developing the photoresist layer to create a plurality of regularly spaced parallel lines in the photoresist;
trimming each of the plurality of regularly spaced parallel lines such that the ratio of line width to line spacing is about 33%;
etching the template to form a plurality of regularly spaced parallel lines in the template; and
removing the photoresist layer.

4. The method according to claim 1, further comprising cropping the plurality of sidewall lines.

5. The method according to claim 1, further comprising:
applying a positive-tone photoresist;
exposing portions of the photoresist covering sidewall lines using photolithography; wherein the exposed portions of the photoresist-covered sidewall lines are configured to introduce features within at least one sidewall line; and
developing the photoresist and etch portions of sidewall lines using photoresist as etch mask, wherein the etching removes portions of the exposed sidewall lines.

6. The method according to claim 1, further comprising:
applying a negative-tone photoresist;
exposing portions of the photoresist-covered sidewall lines using photolithography; wherein the exposed portions of the sidewall lines are configured to introduce features within at least one sidewall line; and
developing photoresist and etch portions of the sidewall lines using photoresist as etch mask, wherein the etching removes portions of the unexposed sidewall lines.

7. The method according to claim 1, wherein the plurality of regularly spaced parallel lines on the template have a half pitch including and in between 22 nm and 30 nm.

8. The method according to claim 1, wherein the plurality of sidewall lines have a half pitch including and in between 11 nm and 15 nm.

9. The method according to claim 1, wherein said interference lithography uses immersion techniques.

10. The method according to claim 1, wherein the sidewalls comprise a dielectric and the sidewalls are deposited using chemical vapor deposition.

11. The method according to claim 1, wherein the template comprises an amorphous carbon hardmask.

12. The method according to claim 1, wherein the template comprises an Advanced Patterning Film.

13. A method for providing printed line widths with a half pitch below 22 nm on a substrate, the method comprising:
providing a plurality of regularly spaced printed lines on a template with a half pitch below 44 nm using interference lithography techniques; and
applying spacers on the longitudinal sides of the plurality of printed lines on the template, wherein the spacers have a half pitch below 22 nm.

14. The method according to claim 13, further comprising:
removing the plurality of printed lines on the template;
applying a positive-tone photoresist onto the template and exposing the template using a photolithography mask, wherein the mask exposes rounded spacer connects formed at the lateral ends of the printed lines during spacer application; developing the resist;
etching the spacers, wherein the etching removes the exposed portions of the spacers; and
removing portions of the substrate not covered by the template.

15. A method for providing an array of regularly spaced printed lines in a semiconductor device, the method comprising:
providing a semiconductor device, wherein the semiconductor device includes a plurality of layers including a substrate, hardmask and photoresist;
exposing a line pattern in the photoresist using interference lithography, wherein the line pattern has a first line width and a first line spacing;
developing the line pattern in the photoresist, wherein after the developing a photoresist line pattern is formed on the hardmask;
trimming the photoresist line pattern; wherein the resulting trimmed line pattern has a second line width and a second line spacing, the second line spacing is equal to approximately three times the second line width, and the second line spacing is narrower than the first line spacing;
etching the hardmask, wherein after the etching a hardmask line pattern is formed in the hardmask;
removing the photoresist;
depositing a spacer film over at least the hardmask line pattern;
etching the spacer film, wherein after the etching a plurality of spacer lines are formed at the sidewalls of the hardmask line pattern, each of the spacer lines have a line width approximately equal to the second line width, the etching results in rounded spacer connects;
removing the hardmask;
cropping the rounded spacer connects; and
etching the substrate, wherein after the etching a plurality of lines are formed in the substrate.

16. The method according to claim 15, wherein the cropping utilizes a photolithography technique.

17. The method according to claim 15, further comprising introducing features in the spacer line pattern using a photolithography technique.

18. The method according to claim 15, further comprising introducing features in the spacer line pattern using E-beam techniques.

19. The method according to claim 15, wherein the cropping comprises:
applying a photoresist,
exposing the photoresist using a trim mask, wherein the trim mask is configured to aid in cropping at least the rounded spacer connects;
developing the photoresist; and
etching the spacers, wherein the etching removes at least the rounded spacers connects.

20. The method according to claim 19, wherein the trim mask is further configured to introduce features in the spacer line pattern.

21. The method according to claim 19, wherein the etching further introduces features in the spacer line pattern.

22. The method according to claim 19, further comprising ashing the photoresist.

23. The method according to claim 15, further comprising cropping the rounded spacer connects and introducing features in the spacer line pattern using the same photolithography process.

24. The method according to claim 15, wherein the photoresist line pattern has a line density of less than or equal to 30 nm half pitch.

25. The method according to claim 15, wherein the spacer line pattern has a line density of less than or equal to 15 nm half pitch.
